(19) United States
(12) Patent Application Publication
(10) Pub. No.: US 2026/0211011 A1
(43) Pub. Date: Jul. 23, 2026

(54) CURRENT MEASURING SYSTEM FOR SWITCHING DEVICES ARRANGED IN A MATRIX CONFIGURATION

(71) Applicant: EATON INTELLIGENT POWER LIMITED, Dublin 4 (IE)

(72) Inventors: Elise MORSKIEFT, Hengelo (NL); Gerard Cornelis SCHOONENBERG, Hengelo (NL)

(21) Appl. No.: 19/138,929

(22) PCT Filed: Dec. 28, 2023
(86) PCT No.: PCT/EP2023/025559

§ 371 Date: Jun. 13, 2025

(30) Foreign Application Priority Data
Jan. 3, 2023 (GB) 2300035.9

(51) Int. Cl. G01R 19/00; G01R 15/18; G01R 15/20; G01R 31/327

(52) U.S. Cl. CPC G01R 19/0092; G01R 15/18; G01R 15/202; G01R 31/3274

(57) ABSTRACT

Some embodiments relate to a measuring system for determining currents through electric switching devices arranged in a matrix configuration and an arrangement, comprising these electric switching devices are disclosed. The measuring system and the arrangement comprise a plurality of current sensors each being associated with one of the switching devices. The current sensors neither surround said switching device nor any electric conductor leading to or from said switching device. Further on, the measuring system and the arrangement comprise a measuring unit, which is designed to receive raw measurement values from the current sensors and to calculate currents through the electric switching device. A current through an electric switching device is calculated based on the raw measurement value received from the current sensor associated with this switching device and based on the raw measurement value received from at least one other of the current sensors.

### CROSS-REFERENCE TO RELATED APPLICATIONS

This application is a national phase filing under 35 C.F.R. § 371 of and claims priority to PCT Patent Application No. PCT/EP2023/025559, filed on Dec. 28, 2023, which claims the benefit of British Application No. 2300035.9, filed on Jan. 3, 2023, the disclosure of each is hereby incorporated by reference in their entirety.

### TECHNICAL FIELD

The presently disclosed subject matter relates to a measuring system for determining currents through electric switching devices arranged in a matrix configuration, which comprises a plurality of current sensors, and a measuring unit, which is designed to receive raw measurement values from the current sensors. A current sensor of the current sensors each is associated with and arranged in the vicinity of one of the switching devices without surrounding said switching device and without surrounding any electric conductor leading to or from said switching device. Additionally, the presently disclosed subject matter relates to an arrangement, which comprises electric switching devices arranged in a matrix configuration and a measuring system of the above kind, wherein a current sensor of the current sensors each is associated with and arranged in the vicinity of one of the switching devices without surrounding said switching device and without surrounding any electric conductor leading to or from said switching device.

### BACKGROUND ART

A current measuring system for switching devices and an arrangement of the above kind are generally known in prior art. The main aim of switching devices is switching loads to and from a grid. For example, such a switching device may comprise a base body with fixed contacts and a switching cap with moving contacts. If the switching cap is put onto the base body, the switch is closed, if it is removed, the switch is opened. Such switching devices are particularly used for medium voltage (1-52 kV).

In several applications, besides the switching function also the current through theses switching devices is of interest. Accordingly, a current sensor may be arranged in the current path of such a switching device. In some applications, a number of electric switching devices are arranged in a matrix configuration in a rather dense configuration. When current measurement is done based on a contactless principle and no contactless sensor forming a loop around an electric conductor leading to or from said switching device can be applied, magnetic fields emanating from nearby conductors may interfere with and foil the current measurement. Accordingly there is a need for accurate current measurements even under the above conditions.

### SUMMARY OF THE DISCLOSURE

Accordingly, an object of the presently disclosed subject matter is the provision of an improved measuring system and the provision of an improved arrangement. In particular, accurate current measurements shall be provided for switching device arrangements, which are retrofitted with contactless current sensors being arranged in a matrix configuration in a rather dense configuration. More particularly, accurate current measurements shall be provided for switching devices with switching caps being arranged in a matrix configuration.

The object of the presently disclosed subject matter is solved by a measuring system of the type disclosed in the opening paragraph, wherein the measuring unit additionally is designed to calculate currents through the electric switching device based on the raw measurement values, wherein a current through an electric switching device of the electric switching devices is calculated based on the raw measurement value received from the current sensor, which is associated with and arranged closest to this switching device and based on the raw measurement value received from at least one other of the current sensors.

The object of the presently disclosed subject matter furthermore is solved by an arrangement, which comprises electric switching devices arranged in a matrix configuration and a measuring system of the above kind, wherein a current sensor of the current sensors each is associated with and arranged in the vicinity of one of the switching devices without surrounding said switching device and without surrounding any electric conductor leading to or from said switching device.

By use of these measures, magnetic fields caused by neighboring switching devices are taken into account, and accordingly accuracy of current measurements is increased. In particular, accurate current measurements can be provided for switching device arrangements, which are retrofitted with (contactless) current sensors being arranged in a matrix configuration in a rather dense configuration. In particular, the proposed solution provides accurate results even if the electric switching devices and/or if electric conductors leading to or from said switching devices are magnetically unshielded. In particular, each of the electric switching devices can have an associated current sensor. In particular, the measuring system can have as many current sensors as switching devices. However, the measuring system can also have a lower number of current sensors.

For example, the current sensors can be embodied as pick-up coils with or without a ferro-magnetic core or can be embodied as Hall sensors. These techniques are known per se and provide contactless measurement of the current through the electric switching device by use of proven means.

Beneficially, a current sensor of the current sensors each can be arranged in or on a protection cap or switching cap of a switching device of the electric switching devices. In this way, switching device arrangements can easily be retrofitted with the current sensors, which in addition are well protected from unfavorable environmental conditions by the cap. As said above, a switching device may comprise a base body with fixed contacts and a switching cap with moving contacts. In such a case, retrofitting can be done in a very easy way by putting the current sensors into the switching cap of a switching device and without fearing a poor measuring accuracy. Generally, it is of advantage if the protection cap or switching cap is made of solid insulation/plastics. In this way, an undesired shielding of the magnetic field emitted by the switching device can be avoided.

Further advantageous embodiments are disclosed in the claims and in the description as well as in the figures.

Beneficially, the measuring unit can be designed to calculate a current through an electric switching device of the electric switching devices based on the raw measurement value received from the current sensor, which is arranged closest to said switching device, minus a weighted raw measurement value received from the at least one other of the current sensors. Tests have shown that the influence of the magnetic field radiated by nearby switching devices can be considered as a percentage of the current flowing through the switching device in question, even in case of alternating current and taken the phase shift of the current in the other conductors into account. In this way, consideration of other raw measurement values can be done with an easy mathematic operation.

The measuring unit can be designed to calculate a current through an electric switching device of the electric switching devices based on the raw measurement value received from the current sensor, which is arranged closest to said switching device and based on the raw measurement values received
a) from all other current sensors or
b) from all directly neighboring current sensors.

In particular, the measuring unit can be designed to calculate a current through an electric switching device of the electric switching devices based on the raw measurement value received from the current sensor, which is arranged closest to said switching device, minus weighted raw measurement values received
a) from all other current sensors or
b) from all directly neighboring current sensors.

In case a), very accurate current measurements can be done, whereas in case b) calculation effort is reduced.

In a very advantageous embodiment of the measuring system, the measuring unit can be designed to calculate a current based on the mathematic matrix operation

$$I = M \cdot K$$

wherein I is a 1×n matrix of the currents through the electric switching devices, M is a 1×n matrix of the raw measurement values received from the current sensors and K is a n×n matrix of weighting factors and n is the number of current sensors.

Alternatively, the measuring unit can be designed to calculate a current based on the mathematic matrix operation

$${I}^{′} = {K}^{′} \cdot {M}^{′}$$

wherein I′ is a n×1 matrix of the currents through the electric switching devices, M′ is a n×1 matrix of the raw measurement values received from the current sensors and K′ is a n×n matrix of weighting factors and n is the number of current sensors.

In both cases, the currents through the electric switching devices can be calculated by means of a mathematic matrix operation and hence in a very efficient way. Weighting factors can be measured individually for different conductor layouts, for example in a test set up.

Beneficially, the raw measurement values received from the current sensors can be linearized before the currents through the electric switching devices are calculated. In this way, non-linearities of the current sensors can be taken into consideration.

### BRIEF DESCRIPTION OF DRAWINGS

The presently disclosed subject matter now is described in more detail hereinafter with reference to particular embodiments, which the presently disclosed subject matter however is not limited to.

FIG. 1 shows an example of a switching arrangement with a frame and a number of switching devices in a matrix configuration;

FIG. 2 shows an exemplary and schematic cross section of a switching unit with three single pole switching devices;

FIG. 3 shows a detailed cross section of a switching device in the closed position;

FIG. 4 shows a detailed cross section of a switching device in the open position;

FIG. 5 shows a switching device with a current sensor in a switching cap in exploded view and

FIG. 6 shows a schematic view of an example for a measuring system with a measuring unit.

### DETAILED DESCRIPTION

Generally, same parts or similar parts are denoted with the same/similar names and reference signs. The features disclosed in the description apply to parts with the same/similar names respectively same/similar reference signs. Indicating the orientation and relative position is related to the associated figure, and indication of the orientation and/or relative position has to be amended in different figures accordingly as the case may be.

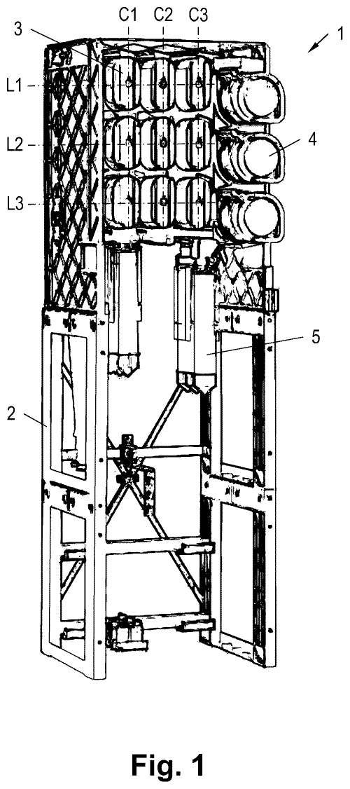

FIG. 1 shows an example of a switching arrangement 1 with a frame 2 and a number of switching devices 3, which are arranged in the frame 2 in a matrix configuration. The switching devices 3 are arranged in three lines L1 . . . . L3 and three columns C1 . . . . C3. However, other arrangements are possible as well in principle. Moreover, the switching arrangement 1 comprises optional fuses 4 and cable boxes 5, which are provided to connect a grid to the switching arrangement 1.

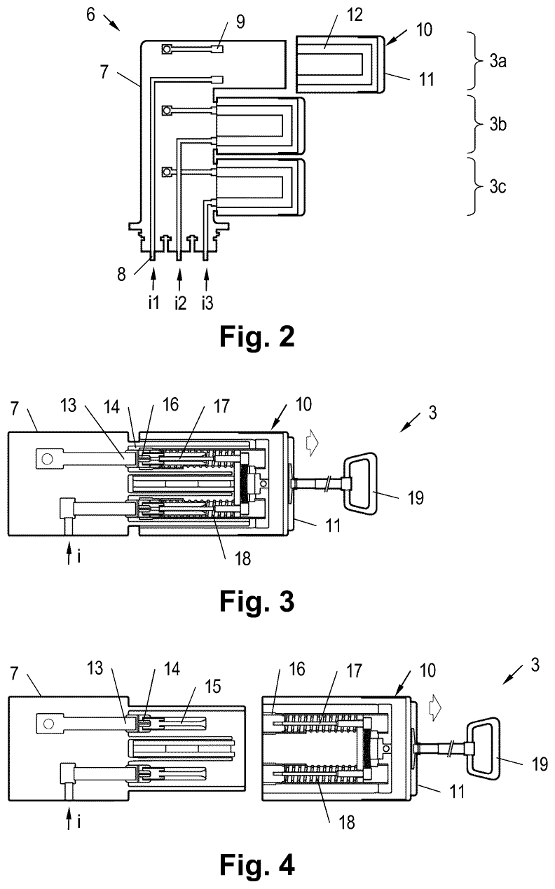

FIG. 2 shows an exemplary and schematic cross section of a switching unit 6 with three switching devices 3a . . . 3c in one of the three columns C1 . . . . C3. The switching unit 6 comprises a base body 7 with terminals 8 for connecting cables to the switching unit 6. Each of the switching devices 3a . . . 3c comprises fixed contacts 9 and a switching cap 10, comprising a switching cap body 11 with a contact bridge 12 arranged therein. When the switching cap 10 is pulled off the fixed contacts 9, the switching devices 3a . . . 3c are open (see the switching device 3a in FIG. 2), when the switching cap 10 is on the fixed contacts 9, the switching devices 3a . . . 3c are closed (see switching devices 3b, 3c in FIG. 2) and the currents i1 . . . i3 may flow.

FIGS. 3 and 4 now show more detailed cross sections of a switching device 3, FIG. 3 in the closed position and FIG. 4 in the open position. Concretely, in the base body 7 of the switching device 3 there is arranged a fixed main contact 13 with a fixed arcing contact 14 and an arcing chamber 15. In the switching cap body 11 there is arranged a moving main contact 16 with a moving arcing contact 17 and an opening spring 18. Moreover, a handle 19 is fixed to the switching cap body 11. When the switching cap 10 is moved on the base body 7, the switching device 3 is closed an the current i may flow, when the switching cap 10 is moved from the base body 7 by use of the handle 19, the switching device 3 is open. The switching devices 3, 3a . . . 3c and their function are known per se and hence are not explained in more detail here.

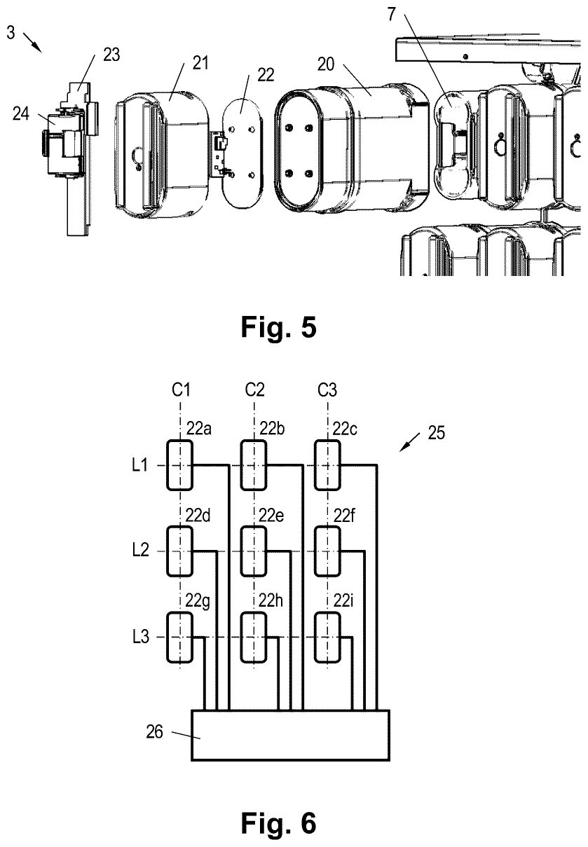

FIG. 5 now shows a special embodiment of a switching device 3 in exploded view. The switching device 3 comprises a switching cap with a switching cap base body 20, a switching cap cover 21, a current sensor 22, a battery holder 23 and a battery 24. As can be seen in FIG. 5, the current sensor 22 is arranged in a hollow space formed by the switching cap base body 20 and the switching cap cover 21. The current sensor 22 is powered by the battery 24, which is fixed to the switching cap cover 21 by use of the battery holder 23. It should be noted that FIG. 5 just shows an exemplary embodiment for arranging a current sensor 22 in the vicinity of a switching device 3, and other arrangements are possible as well. For example, the battery 24 can be arranged within the switching cap cover 21, too, and so on. In particular, the switching cap base body 20 and the switching cap cover 21 can be made from solid insulation like epoxy resin or plastics.

Generally the current sensor 22 can be embodied as a pick-up coil with or without a ferro-magnetic core or can be embodied as a Hall sensor. These techniques provide contactless measurement of the current i, i1 . . . i3 through the electric switching device 3.

FIG. 6 now shows a schematic view of an example for a measuring system 25, which comprises a number of current sensors 22a . . . 22i arranged in a matrix formed by three lines L1 . . . . L3 and three columns C1 . . . . C3 and relates to the arrangement of electric switching devices 3a . . . 3c depicted in FIG. 1. The measuring system 25 also comprises a measuring unit 26, which is designed to receive raw measurement values from the current sensors 22a . . . 22i.

So, an arrangement is proposed, which comprises a number of electric switching devices 3, 3a . . . 3c arranged in a matrix configuration and a measuring system 25 as outlined above. The measuring system 25 comprises a number of current sensors 22, 22a . . . 22i each being associated with and arranged in the vicinity of one of the switching devices 3, 3a . . . 3c. The current sensors 22, 22a . . . 22i neither surround said switching device 3, 3a . . . 3c nor surround any electric conductor leading to or from said switching device 3, 3a . . . 3c. In particular, the electric switching devices 3, 3a . . . 3c may be magnetically unshielded. In particular, the electric conductors leading to or from said switching devices 3, 3a . . . 3c may be magnetically unshielded as well.

Generally, it may be the case that just some of the switching devices 3, 3a . . . 3c have an associated current sensor 22, 22a . . . 22i. However, beneficially, each of the electric switching devices 3, 3a . . . 3c can have an associated current sensor 22, 22a . . . 22i. In particular, the measuring system 25 can have as many current sensors 22, 22a . . . 22i as switching devices 3, 3a . . . 3c.

The measuring unit 26 is designed to calculate currents i, i1 . . . i3 through the electric switching devices 3, 3a . . . 3c based on the raw measurement values, wherein a current i, i1 . . . i3 through an electric switching device 3, 3a . . . 3c of the electric switching devices 3, 3a . . . 3c is calculated based on the raw measurement value received from the current sensor 22, 22a . . . 22i, which is associated with and arranged closest to this switching device 3, 3a . . . 3c and based on the raw measurement value received from at least one other of the current sensors 22, 22a . . . 22i. In this way, magnetic fields caused by neighboring switching devices 3, 3a . . . 3c can be taken into account.

In particular, the current calculation can be based on the raw measurement values received from all other current sensors 22, 22a . . . 22i or from all directly neighboring current sensors 22, 22a . . . 22i. So, if for example the current trough the switching device 3a associated with the current sensor 22a shall be calculated, in addition to the raw measurement value of current sensor 22a, the raw measurement values of all other current sensors 22b . . . 22i are taken into account in the first case or the raw measurement values of all directly neighboring current sensors 22b, 22d, 22e are taken into account in the second case. In the first case, very accurate current measurements can be done, whereas in the second case calculation effort is reduced.

Generally, consideration of other raw measurement values can be done by subtracting weighted raw measurement values received by the other of the current sensors 22, 22a . . . 22i from the raw measurement value associated with the switching device 3, 3a . . . 3c in question. Beneficially, consideration of other raw measurement values can be done with an easy mathematic operation in this way.

Generally, the raw measurement values received from the current sensors 22, 22a . . . 22i can be linearized before the currents i, i1 . . . i3 through the electric switching devices 3, 3a . . . 3c are calculated. In this way, non-linearities of the current sensors 22, 22a . . . 22i can be taken into consideration.

In a very advantageous embodiment, the measuring unit 26 is designed to do the calculations based on a mathematic matrix operation. Concretely, the measuring unit 26 can be designed to calculate a current i, i1 . . . i3 based on the mathematic matrix operation

$$I = M \cdot K$$

wherein I is a 1×n matrix of the currents i, i1 . . . i3 through the electric switching devices 3, 3a . . . 3c, M is a 1×n matrix of the raw measurement values received from the current sensors 22, 22a . . . 22i and K is a n×n matrix of weighting factors and n is the number of current sensors 22, 22a . . . 22i.

Alternatively, the measuring unit 26 can be designed to calculate a current i, i1 . . . i3 based on the mathematic matrix operation

$${I}^{′} = {K}^{′} \cdot {M}^{′}$$

wherein I′ is a n×1 matrix of the currents i, i1 . . . i3 through the electric switching devices 3, 3a . . . 3c, M′ is a n×1 matrix of the raw measurement values received from the current sensors 22, 22a . . . 22i and K′ is a n×n matrix of weighting factors and n is the number of current sensors 22, 22a . . . 22i.

In reality, the switching arrangement 1, the electric switching devices 3, 3a . . . 3c and other parts shown in the figures may have more or less parts than shown in said figures. Moreover, the description may comprise subject matter of further independent inventions.

It should also be noted that the term “comprising” does not exclude other elements and the use of articles “a” or “an” does not exclude a plurality. Also elements described in association with different embodiments may be combined. It should also be noted that reference signs in the claims should not be construed as limiting the scope of the claims.

### LIST OF REFERENCE NUMERALS

1 switching arrangement
2 frame
3, 3a . . . 3c electric switching device
4 fuse
5 cable box
6 switching unit
7 base body
8 terminal
9 fixed contact
10 switching cap
11 switching cap body
12 contact bridge
13 fixed main contact
14 fixed arcing contact
15 arcing chamber
16 moving main contact
17 moving arcing contact
18 opening spring
19 handle
20 switching cap base body
21 switching cap cover
22, 22a . . . 22i current sensor
23 battery holder
24 battery
25 measuring system
26 measuring unit
C1 . . . . C3 column
L1 . . . . L3 line
i, i1 . . . i3 current

1. A Measuring system for determining currents through electric switching devices arranged in a matrix configuration, comprising:
a plurality of current sensors wherein a current sensor of the current sensors each is associated with and arranged in the vicinity of one of the switching devices without surrounding said switching device and without surrounding any electric conductor leading to or from said switching device, and
a measuring unit, which is designed to receive raw measurement values from the current sensors,
wherein
the measuring unit additionally is designed to calculate currents through the electric switching device based on the raw measurement values, wherein a current through an electric switching device of the electric switching devices is calculated based on the raw measurement value received from the current sensor, which is associated with and arranged closest to this switching device and based on the raw measurement value received from at least one other of the current sensors.

2. The Measuring system as claimed in claim 1, wherein each of the electric switching devices has an associated current sensor of the current sensors.

3. The Measuring system as claimed in claim 1, wherein the measuring unit is designed to calculate a current through an electric switching device of the electric switching devices of based on the raw measurement value received from the current sensor, which is arranged closest to said switching device, minus a weighted raw measurement value received from the at least one other of the current sensors.

4. The Measuring system as claimed in claim 1, wherein the measuring unit is designed to calculate a current through an electric switching device of the electric switching devices based on the raw measurement value received from the current sensor which is arranged closest to said switching device and based on the raw measurement values received
a) from all other current sensors or
b) from all directly neighboring current sensors.

5. The Measuring system as claimed in claim 1, wherein the measuring unit is designed to calculate a current through an electric switching device of the electric switching devices based on the raw measurement value received from the current sensor, which is arranged closest to said switching device, minus weighted raw measurement values received
a) from all other current sensors or
b) from all directly neighboring current sensors.

6. The Measuring system as claimed in claim 5, wherein the measuring unit is designed to calculate a current based on the mathematic matrix operation
$$I = M \cdot K$$
wherein I is a 1×n matrix of the currents through the electric switching devices, M is a 1×n matrix of the raw measurement values received from the current sensors and K is a n×n matrix of weighting factors and n is the number of current sensors, or based on the mathematic matrix operation
$${I}^{′} = {K}^{′} \cdot {M}^{′}$$
wherein I′ is a n×1 matrix of the currents through the electric switching devices M′ is a n×1 matrix of the raw measurement values received from the current sensors and K′ is a n×n matrix of weighting factors and n is the number of current sensors.

7. The Measuring system as claimed in claim 1, wherein raw measurement values received from the current sensors are linearized before the currents through the electric switching devices are calculated.

8. The Measuring system as claimed in claim 1, wherein the current sensors are embodied as pick-up coils with or without a ferro-magnetic core or as Hall sensors.

9. An Arrangement, comprising electric switching devices arranged in a matrix configuration,
wherein
a measuring system, as claimed in claim 1, wherein a current sensor of the current sensors each is associated with and arranged in the vicinity of one of the switching devices without surrounding said switching device and without surrounding any electric conductor leading to or from said switching device.

10. The Arrangement as claimed in claim 9, wherein a current sensor of the current sensors each is arranged in or on a protection cap or switching cap of a switching device of the electric switching devices.

11. The Arrangement as claimed in claim 10, wherein the protection cap or switching cap is made of plastics.

12. The Arrangement as claimed in claim 9, wherein the electric switching devices are magnetically unshielded.

13. The Arrangement as claimed in claim 9, wherein the electric conductors leading to or from said switching devices are magnetically unshielded.
